(19) United States
(12) Patent Application Publication
(10) Pub. No.: US 2026/0095151 A1
(43) Pub. Date: Apr. 2, 2026

(54) MULTIPLEXER

(71) Applicant: Murata Manufacturing Co., Ltd., Nagaokakyo-shi (JP)

(72) Inventor: Toshiaki TAKATA, Nagaokakyo-shi (JP)

(21) Appl. No.: 19/341,507

(22) Filed: Sep. 26, 2025

(30) Foreign Application Priority Data
Oct. 1, 2024 (JP) 2024-171935

(51) Int. Cl. H03H 9/70; H03H 9/13; H03H 9/56

(52) U.S. Cl. CPC H03H 9/70; H03H 9/133; H03H 9/568

(57) ABSTRACT

A multiplexer includes a common connection terminal, and transmitting and receiving filters commonly connected to the common connection terminal. The transmitting and receiving filters each include a resonator. The resonators of the transmitting and receiving filters share a piezoelectric substrate. The resonator located closest to the common connection terminal in terms of a circuit configuration of the transmitting filter defines a series-arm resonator. The resonator located closest to the common connection terminal in terms of a circuit configuration of the receiving filter defines a longitudinally coupled resonator acoustic wave filter. The series-arm resonator of the transmitting filter includes an IDT electrode including a plurality of electrode fingers. The first longitudinally coupled resonator acoustic wave filter of the receiving filter includes a plurality of IDT electrodes each including a plurality of electrode fingers.

### CROSS REFERENCE TO RELATED APPLICATIONS

This application claims the benefit of priority to Japanese Patent Application No. 2024-171935 filed on Oct. 1, 2024. The entire contents of this application are hereby incorporated herein by reference.

### BACKGROUND OF THE INVENTION

### 1. Field of the Invention

The present invention relates to multiplexers each including an acoustic wave resonator.

### 2. Description of the Related Art

Conventionally, multiplexers have been widely used as filters for mobile phones, and the like. International Publication No. 2018/012274 discloses an example of a duplexer. In this duplexer, a transmitting filter and a receiving filter are connected in common to an antenna terminal. The transmitting filter is a ladder filter. In the transmitting filter, in terms of a circuit configuration, a series-arm resonator is located closest to the antenna terminal. The receiving filter is a longitudinally coupled resonator filter.

In a duplexer described in International Publication No. 2018/012274, when viewed from an antenna terminal, impedance characteristics of a receiving filter in a pass band of a transmitting filter are close to a short side. For this reason, a signal may leak from the transmitting filter to the receiving filter. In this case, the signal flows into a longitudinally coupled resonator filter as the receiving filter, that is, a longitudinally coupled resonator acoustic wave filter. This causes the longitudinally coupled resonator filter to be easily damaged.

In contrast, in the receiving filter, when a series-arm resonator is positioned closer to the antenna terminal than the longitudinally coupled resonator acoustic wave filter, the impedance characteristics may be brought closer to an open side. In this case, the signal is less likely to leak from the transmitting filter to the receiving filter. However, there arises a need to increase a size of a multiplexer because the series-arm resonator is provided.

### SUMMARY OF THE INVENTION

Example embodiments of the present invention provide multiplexers each able to reduce or prevent damage to a longitudinally coupled resonator acoustic wave filter without an increase in size.

A multiplexer according to an example embodiment of the present invention includes a common connection terminal, and a transmitting filter and a receiving filter connected in common to the common connection terminal. The transmitting filter and the receiving filter each include a resonator. The resonator of the transmitting filter and the resonator of the receiving filter share a piezoelectric substrate. The resonator located closest to the common connection terminal in terms of a circuit configuration of the transmitting filter is a series-arm resonator. The resonator located closest to the common connection terminal in terms of a circuit configuration of the receiving filter is a longitudinally coupled resonator acoustic wave filter. The series-arm resonator of the transmitting filter includes an IDT electrode including a plurality of electrode fingers, and the longitudinally coupled resonator acoustic wave filter of the receiving filter includes a plurality of IDT electrodes each including a plurality of electrode fingers. In each of the IDT electrodes of the longitudinally coupled resonator acoustic wave filter and the series-arm resonator, when a direction in which the plurality of electrode fingers extends is denoted as an electrode finger extension direction and a direction orthogonal or substantially orthogonal to the electrode finger extension direction is denoted as an electrode finger orthogonal direction. A region where the electrode fingers adjacent to each other in the electrode finger orthogonal direction overlap is denoted as a crossover region, and a dimension of the crossover region along the electrode finger extension direction is denoted as a crossover width. When in the transmitting filter, a product of a number of the plurality of electrode fingers of the IDT electrode of the series-arm resonator and the crossover width is denoted as C1, and in the receiving filter, when a total value of a product of a number of the plurality of electrode fingers of each of the plurality of IDT electrodes of the longitudinally coupled resonator acoustic wave filter and the crossover width is denoted as TC2, TC2<C1.

A multiplexer according to an example embodiment of the present invention includes a common connection terminal, and a transmitting filter and a receiving filter connected in common to the common connection terminal. The transmitting filter and the receiving filter each include a resonator. The resonator of the transmitting filter and the resonator of the receiving filter share a piezoelectric substrate. The resonator located closest to the common connection terminal in terms of a circuit configuration of the transmitting filter is a series-arm resonator. The resonator located closest to the common connection terminal in terms of a circuit configuration of the receiving filter is a longitudinally coupled resonator acoustic wave filter. The series-arm resonator of the transmitting filter includes an IDT electrode including a plurality of electrode fingers, and the longitudinally coupled resonator acoustic wave filter of the receiving filter includes a plurality of IDT electrodes each including a plurality of electrode fingers. Electrostatic capacitance of the longitudinally coupled resonator acoustic wave filter of the receiving filter is smaller than electrostatic capacitance of the series-arm resonator of the transmitting filter.

According to multiplexers according to example embodiments of the present invention, it is possible to reduce or prevent damage to a longitudinally coupled resonator acoustic wave filter without increasing a size.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit diagram of a duplexer according to a first example embodiment of the present invention.

FIG. 2 is a plan view of the duplexer according to the first example embodiment of the present invention.

FIG. 3 is a schematic plan view illustrating a first longitudinally coupled resonator acoustic wave filter and a second longitudinally coupled resonator acoustic wave filter of a receiving filter in the first example embodiment of the present invention.

FIG. 4 is a schematic plan view illustrating a series-arm resonator of a transmitting filter according to the first example embodiment of the present invention.

FIG. 5 is a circuit diagram of a duplexer according to a first comparison example.

FIG. 6 is a Smith chart illustrating impedance characteristics of a receiving filter in a pass band of a transmitting filter in the first comparison example, when viewed from a common connection terminal.

FIG. 7 is a Smith chart illustrating impedance characteristics of a receiving filter in a pass band of a transmitting filter in a second comparison example, when viewed from a common connection terminal.

FIG. 8 is a Smith chart illustrating impedance characteristics of the receiving filter in a pass band of a transmitting filter in the first example embodiment of the present invention, when viewed from a common connection terminal.

FIG. 9 is a plan view of a duplexer according to the first comparison example.

FIG. 10 is a diagram illustrating consumed power of a series-arm resonator located closest to the common connection terminal in terms of a circuit configuration of the transmitting filter and consumed power of a first longitudinally coupled resonator acoustic wave filter of the receiving filter, in the first example embodiment, the first comparison example, and the second comparison example of the present invention.

FIG. 11 is a diagram illustrating attenuation frequency characteristics of the transmitting filters in the first example embodiment, the first comparison example, and the second comparison example of the present invention.

FIG. 12 is a diagram illustrating the attenuation frequency characteristics of the receiving filters in the first example embodiment, the first comparison example, and the second comparison example of the present invention.

FIG. 13 is a schematic diagram of a multiplexer according to a second example embodiment of the present invention.

### DETAILED DESCRIPTION OF THE EXAMPLE EMBODIMENTS

In the following, example embodiments of the present invention will be described with reference to the drawings.

In addition, the example embodiments described herein are each illustrative, and partial substitution or combination of configurations is possible among different example embodiments.

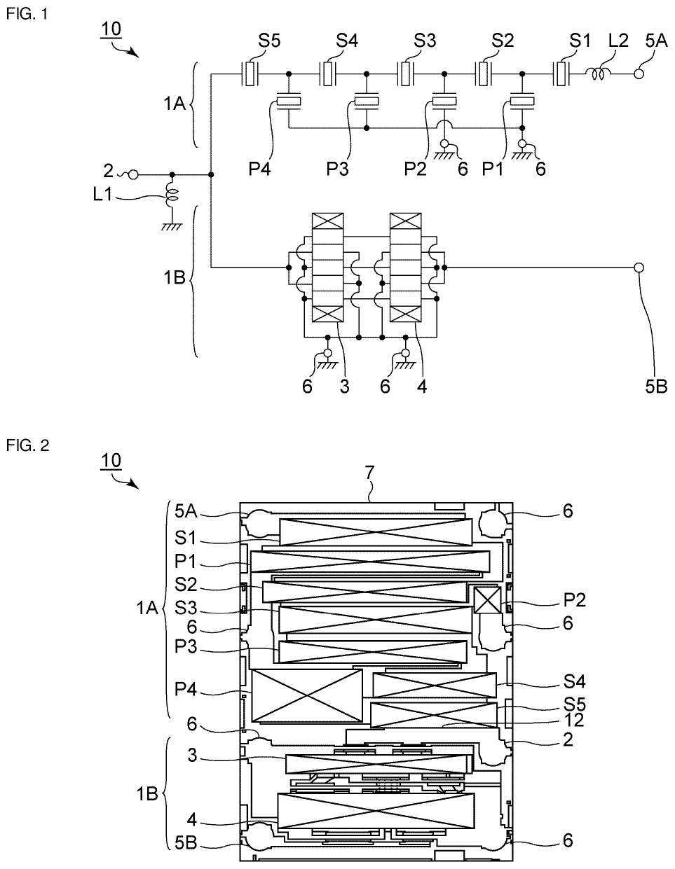

FIG. 1 is a circuit diagram of a duplexer according to a first example embodiment of the present invention.

A duplexer 10 is a multiplexer according to the first example embodiment of the present invention. More specifically, the duplexer 10 includes a transmitting filter 1A, a receiving filter 1B, an inductor L1, and a common connection terminal 2. The common connection terminal 2 is, for example, an antenna terminal. The antenna terminal is a terminal connected to an antenna. The common connection terminal 2 might not necessarily be an antenna terminal.

The transmitting filter 1A and the receiving filter 1B are connected in common to the common connection terminal 2. The inductor L1 is connected between the common connection terminal 2 and a reference potential. Nevertheless, the inductor L1 might not necessarily be provided.

The multiplexers according to example embodiments of the present invention are not limited to a duplexer. The multiplexer according to example embodiments of the present invention may include at least one filter device other than the transmitting filter and the receiving filter, for example.

In this specification, a pass band of a multiplexer or a filter device is a band defined by a standard such as a communication band. The communication band of the duplexer 10 is, for example, Band 12. Therefore, the pass band of the transmitting filter 1A is, for example, about 699 MHz to about 716 MHz as a transmitting band of Band 12. The pass band of the receiving filter 1B is, for example, about 729 MHz to about 746 MHz as a receiving band of Band 12. The pass bands of the transmitting filter 1A and the receiving filter 1B are not limited to the foregoing.

As illustrated in FIG. 1, the transmitting filter 1A is, for example, a ladder filter. Specifically, the transmitting filter 1A includes a plurality of series-arm resonators and a plurality of parallel-arm resonators, an inductor L2, and a first signal terminal 5A. The plurality of series-arm resonators and the plurality of the parallel-arm resonators are all acoustic wave resonators.

Specifically, the plurality of series-arm resonators include a series-arm resonator S1, a series-arm resonator S2, a series-arm resonator S3, a series-arm resonator S4, and a series-arm resonator S5. In terms of a circuit configuration, the series-arm resonator S1, the series-arm resonator S2, the series-arm resonator S3, the series-arm resonator S4, and the series-arm resonator S5 are arranged in this order from a side of the first signal terminal 5A. The inductor L2 is connected between the first signal terminal 5A and the series-arm resonator S1.

Specifically, the plurality of parallel-arm resonators include a parallel-arm resonator P1, a parallel-arm resonator P2, a parallel arm resonator P3, and a parallel-arm resonator P4. Each of the parallel-arm resonators is connected to a reference potential. More specifically, the duplexer 10 includes a plurality of reference potential terminals 6. The reference potential terminals 6 are terminals connected to the reference potential. Each of the parallel-arm resonators is connected to the reference potential with the reference potential terminal 6 interposed therebetween.

More particularly, the parallel-arm resonator P1 is connected between a connection point between the series-arm resonator S1 and the series-arm resonator S2, and the reference potential terminal 6. The parallel-arm resonator P2 is connected between a connection point between the series-arm resonator S2 and the series-arm resonator S3, and the reference potential terminal 6. The parallel-arm resonator P3 is connected between a connection point between the series-arm resonator S3 and the series-arm resonator S4, and the reference potential terminal 6. The parallel-arm resonator P4 is connected between a connection point between the series-arm resonator S4 and the series-arm resonator S5, and the reference potential terminal 6.

On the other hand, the receiving filter 1B includes a first longitudinally coupled resonator acoustic wave filter 3, a second longitudinally coupled resonator acoustic wave filter 4, and a second signal terminal 5B. In terms of the circuit configuration, the first longitudinally coupled resonator acoustic wave filter 3 and the second longitudinally coupled resonator acoustic wave filter 4 are disposed between the common connection terminal 2 and the second signal terminal 5B. Circuit configurations of the transmitting filter 1A and the receiving filter 1B are not limited to the foregoing.

In the following, the acoustic wave resonators, the series-arm resonators, the parallel-arm resonators, and the longitudinally coupled resonator acoustic wave filters may be collectively referred to as resonators.

FIG. 2 is a plan view of the duplexer according to the first example embodiment. In FIG. 2, each resonator is illustrated in a sketch in which two diagonal lines are added to a rectangle. This sketch diagram includes both an IDT (Interdigital Transducer) electrode and a reflector which are described below. This also applies to sketch plan views other than FIG. 2.

The duplexer 10 includes a piezoelectric substrate 7. The piezoelectric substrate 7 is a substrate with piezoelectricity. The piezoelectric substrate 7 includes only of piezoelectric materials. For example, as the piezoelectric materials, lithium tantalate, lithium niobate, zinc oxide, aluminum oxide, crystal, or Lead Zirconate Titanate (PZT), or the like can be used. The piezoelectric substrate 7 may be a laminated substrate including a piezoelectric layer.

The common connection terminal 2, the first signal terminal 5A, the second signal terminal 5B, and the plurality of reference potential terminals 6 are provided on the piezoelectric substrate 7. Each of the above terminals is defined by an electrode pad. Nevertheless, the each of the above terminals may be defined by wiring.

In the duplexer 10, a resonator of the transmitting filter 1A and a resonator of the receiving filter 1B share the piezoelectric substrate 7. More specifically, the plurality of resonators in the duplexer 10 include a plurality of the IDT electrodes being provided on the same piezoelectric substrate 7. In the following, the configurations of the resonators will be described in detail.

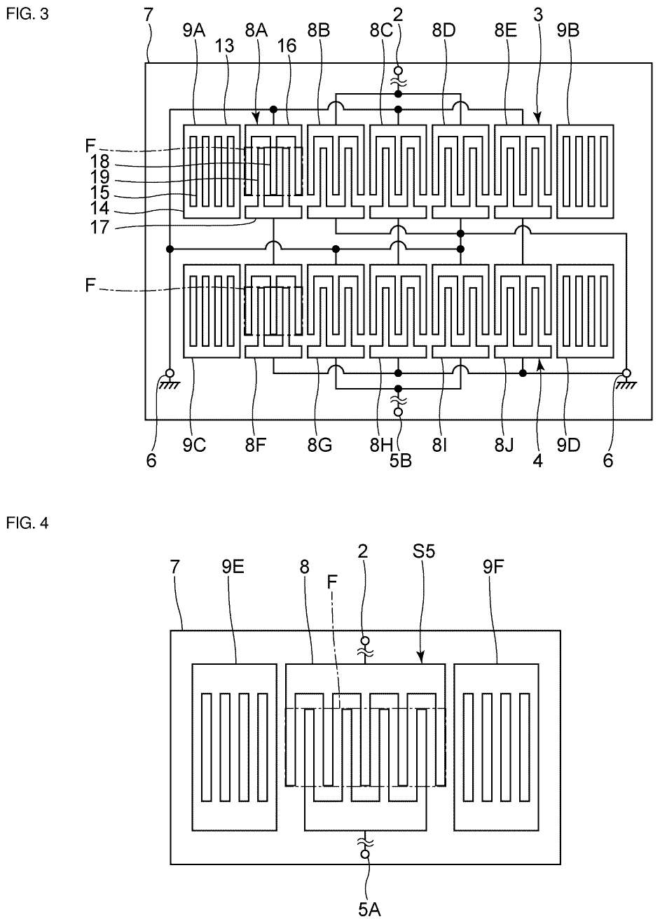

FIG. 3 is a schematic plan view illustrating the first longitudinally coupled resonator acoustic wave filter and the second longitudinally coupled resonator acoustic wave filter of the receiving filter in the first example embodiment.

The first longitudinally coupled resonator acoustic wave filter 3 includes the piezoelectric substrate 7 and five IDT electrodes, for example. Specifically, the five IDT electrodes in the first longitudinally coupled resonator acoustic wave filter 3 include an IDT electrode 8A, an IDT electrode 8B, an IDT electrode 8C, an IDT electrode 8D, and an IDT electrode 8E. The number of the IDT electrodes of the first longitudinally coupled resonator acoustic wave filter 3 is not limited to five. The first longitudinally coupled resonator acoustic wave filter 3 may include a plurality of IDT electrodes such as three, seven, or nine, for example.

The IDT electrode 8A of the first longitudinally coupled resonator acoustic wave filter 3 includes a pair of busbars and a plurality of electrode fingers. Specifically, the pair of busbars include a first busbar 16 and a second busbar 17. The first busbar 16 and the second busbar 17 face each other. Specifically, the plurality of electrode fingers include a plurality of first electrode fingers 18 and a plurality of second electrode fingers 19. One end of each of the plurality of first electrode fingers 18 is connected to the first busbar 16. One end of each of the plurality of second electrode fingers 19 is connected to the second busbar 17. The plurality of first electrode fingers 18 and the plurality of second electrode fingers 19 are interdigitated with each other.

In the IDT electrode 8A, the first busbar 16 and the plurality of first electrode fingers 18 are connected to the reference potential. On the other hand, the second busbar 17 and the plurality of second electrode fingers 19 reconnected to a signal potential.

In the following, the first busbar 16 and the second busbar 17 may be collectively referred to simply as busbars. The first electrode fingers 18 and the second electrode fingers 19 may be collectively referred to simply as electrode fingers. A direction in which the plurality of electrode fingers extend is an electrode finger extension direction, and a direction orthogonal or substantially orthogonal to the electrode finger extension direction is an electrode finger orthogonal direction.

Similarly to the IDT electrode 8A, the IDT electrodes other than the IDT electrode 8A of the first longitudinally coupled resonator acoustic wave filter 3 also include a pair of busbars and a plurality of electrode fingers. The electrode finger orthogonal direction in each of the IDT electrodes of the first longitudinally coupled resonator acoustic wave filter 3 is the same or substantially the same direction. In each of the IDT electrodes, one busbar is connected to the signal potential, and the other busbar is connected to the signal potential.

When an alternating current voltage is applied to each of the IDT electrodes, an acoustic wave is excited. An acoustic wave propagation direction in each of the IDT electrodes is parallel or substantially parallel to the electrode finger orthogonal direction. The plurality of IDT electrodes of the first longitudinally coupled resonator acoustic wave filter 3 are arranged in the acoustic wave propagation direction. Specifically, the plurality of IDT electrodes is arranged in the order of the IDT electrode 8A, the IDT electrode 8B, IDT electrode 8C, IDT electrode 8D, and IDT electrode 8E.

In the present example embodiment, the first busbars and the plurality of first electrode fingers of the IDT electrode 8A, the IDT electrode 8C, and the IDT electrode 8E are connected to the reference potential. The second busbars and the plurality of second electrode fingers of the IDT electrode 8A, the IDT electrode 8C, and the IDT electrode 8E are connected to the signal potential. Specifically, these second busbars and the plurality of second electrode fingers are connected to an output potential.

The first busbars and the plurality of first electrode fingers of the IDT electrode 8B and the IDT electrode 8D are connected to the signal potential. Specifically, these first busbars and the plurality of first electrode fingers are connected to an input potential. The second busbar and the plurality of second electrode fingers of the IDT electrode 8B and the IDT electrode finger 8D are connected to the reference potential.

When the IDT electrode 8A is viewed from the electrode finger orthogonal direction, a region where the adjacent first electrode finger 18 and the second electrode finger 19 overlap each other is denoted as a crossover region F. The crossover region F is a region of the piezoelectric substrate 7 defined based on a configuration of the IDT electrode 8A. Nevertheless, when the configuration of the IDT electrode 8A is described, it can be said that the crossover region F is a region that the IDT electrode 8A includes. In the first longitudinally coupled resonator acoustic wave filter 3, each of the five IDT electrodes includes a crossover region F. In the following, a dimension along the electrode finger extension direction of the crossover region F is denoted as a crossover width. The crossover widths of a plurality of the crossover regions F in the first longitudinally coupled resonator acoustic wave filter 3 are the same or substantially the same.

The first longitudinally coupled resonator acoustic wave filter 3 includes a pair of reflectors. Specifically, the pair of reflectors include a reflector 9A and a reflector 9B. More specifically, the reflector 9A and the reflector 9B are provided on the piezoelectric substrate 7 so as to face each other with the plurality of IDT electrodes interposed therebetween in the acoustic wave propagation direction. The reflector 9A includes a pair of reflector busbars and a plurality of reflector electrode fingers 15. Specifically, the pair of reflector busbars include a reflector busbar 13 and a reflector busbar 14. Both ends of each of the reflector electrode fingers 15 are short-circuited by the reflector busbar 13 and the reflector busbar 14. The reflector 9B is configured similarly to the reflector 9A.

The second longitudinally coupled resonator acoustic wave filter 4 shares the piezoelectric substrate 7 with the first longitudinally coupled resonator acoustic wave filter 3. Similarly to the first longitudinally coupled resonator acoustic wave filter 3, the second longitudinally coupled resonator acoustic wave filter 4 includes, for example, five IDT electrodes and a pair of reflectors. Specifically, the five IDT electrodes in the second longitudinally coupled resonator acoustic wave filter 4 include an IDT electrode 8F, an IDT electrode 8G, an IDT electrode 8H, an IDT electrode 8I, and an IDT electrode 8J. Specifically, the pair of reflectors include the reflector 9C and the reflector 9D. The number of the IDT electrodes of the second longitudinally coupled resonator acoustic wave filter 4 is not limited to five.

Similarly to each of the IDT electrodes of the first longitudinally coupled resonator acoustic wave filter 3, each of the IDT electrodes of the second longitudinally coupled resonator acoustic wave filter 4 includes a pair of busbars and a plurality of electrode fingers, and includes the crossover region F. In each of the reflector 9C and the reflector 9D, both ends of the plurality of reflector electrode fingers are short-circuited by the pair of reflector busbars.

The first longitudinally coupled resonator acoustic wave filter 3 and the second longitudinally coupled resonator acoustic wave filter 4 each have a single-stage configuration. The first longitudinally coupled resonator acoustic wave filter 3 is connected to the second longitudinally coupled resonator acoustic wave filter 4. This results in a longitudinally coupled resonator acoustic wave filter having a two-stage configuration. Nevertheless, in this specification, the single-stage longitudinally coupled resonator acoustic wave filter is defined as one longitudinally coupled resonator acoustic wave filter. Thus, in example embodiments of the present invention, the first longitudinally coupled resonator acoustic wave filter 3 and the second longitudinally coupled resonator acoustic wave filter 4 are individual resonators.

The receiving filter 1B may include a plurality of the second longitudinally coupled resonator acoustic wave filters 4. In this case, the plurality of second longitudinally coupled resonator acoustic wave filters 4 may be connected to each other. When the receiving filter 1B includes the first longitudinally coupled resonator acoustic wave filter 3 and at least one second longitudinally coupled resonator acoustic wave filter 4, the first longitudinally coupled resonator acoustic wave filter 3 is located closest to the common connection terminal 2, in terms of the circuit configuration. Nevertheless, the receiving filter 1B might not necessarily include the second longitudinally coupled resonator acoustic wave filter 4.

FIG. 4 is a schematic plan view illustrating a series-arm resonator of a transmitting filter according to the first example embodiment.

The series-arm resonator S5 shares the piezoelectric substrate 7 with the resonator of the receiving filter 1B. The series-arm resonator S5 includes the one IDT electrode 8 and a pair of reflectors. Specifically, the pair of reflectors include the reflector 9E and the reflector 9F.

Similarly to each of the IDT electrodes of the first longitudinally coupled resonator acoustic wave filter 3 illustrated in FIG. 3, the IDT electrode 8 of the series-arm resonator S5 includes a pair of busbars and a plurality of electrode fingers, and includes the crossover region F. In each of the reflector 9E and the reflector 9F of the series-arm resonator S5, both ends of the plurality of reflector electrode fingers are short-circuited by the pair of reflector busbars.

As illustrated in FIG. 1, the plurality of series-arm resonators other than the series-arm resonator S5 and the plurality of parallel-arm resonators each have also one IDT electrode and a pair of reflectors. In the present example embodiment, the plurality of series-arm resonators and the plurality of parallel-arm resonators are all acoustic wave resonators.

The electrode finger extension direction, the electrode finger orthogonal direction, and the crossover width are also similarly defined in each of the IDT electrodes and in each of the crossover regions F in the first longitudinally coupled resonator acoustic wave filter 3, the second longitudinally coupled resonator acoustic wave filter 4, the series-arm resonator S5, and the like.

In each of the resonators of the transmitting filter 1A and the receiving filter 1B, each of the IDT electrodes and each of the reflectors may be made of a laminated metal film or alternatively, may be made of a single-layer metal film.

In the present example embodiment, the series-arm resonator S5 is a resonator that is located closest to the common connection terminal 2 in terms of the circuit configuration of the transmitting filter 1A. The first longitudinally coupled resonator acoustic wave filter 3 is a resonator that is located closest to the common connection terminal 2 in terms of the circuit configuration of the receiving filter 1B.

In the following, a product of the number of the plurality of electrode fingers of the IDT electrodes 8 of the series-arm resonator S5 illustrated in FIG. 4 and the crossover width is denoted as C1. When the number of the plurality of electrode fingers of the IDT electrodes 8 of the series-arm resonator S5 is N1 and the crossover width in the crossover region F is denoted as A1, C1=N1×A1.

On the other hand, as illustrated in FIG. 3, a total value of the product of the number of the plurality of electrode fingers of each of the plurality of IDT electrodes of the first longitudinally coupled resonator acoustic wave filter 3 and the crossover width is denoted as TC2. In the present example embodiment, the crossover widths are the same or substantially the same in the plurality of IDT electrodes of the first longitudinally coupled resonator acoustic wave filter 3. Therefore, when the number of the plurality of electrode fingers of the plurality of IDT electrodes of the first longitudinally coupled resonator acoustic wave filter 3 is denoted as N2 and the crossover width of each of the crossover regions F in the first longitudinally coupled resonator acoustic wave filter 3 is denoted as A2, TC2=N2×A2.

The present example embodiment has the following configurations: 1) in terms of the circuit configuration of the transmitting filter 1A, the resonator located closest to the common connection terminal 2 is the series-arm resonator S5, and in the circuit configuration of the receiving filter 1B, the resonator located closest to the common connection terminal 2 is the first longitudinally coupled resonator acoustic wave filter 3, and 2) TC2<C1. This makes it possible to reduce or prevent damage to the first longitudinally coupled resonator acoustic wave filter 3 without increasing the size of the duplexer 10. This will be described below in detail by comparing the present example embodiment with a first comparison example and a second comparison example.

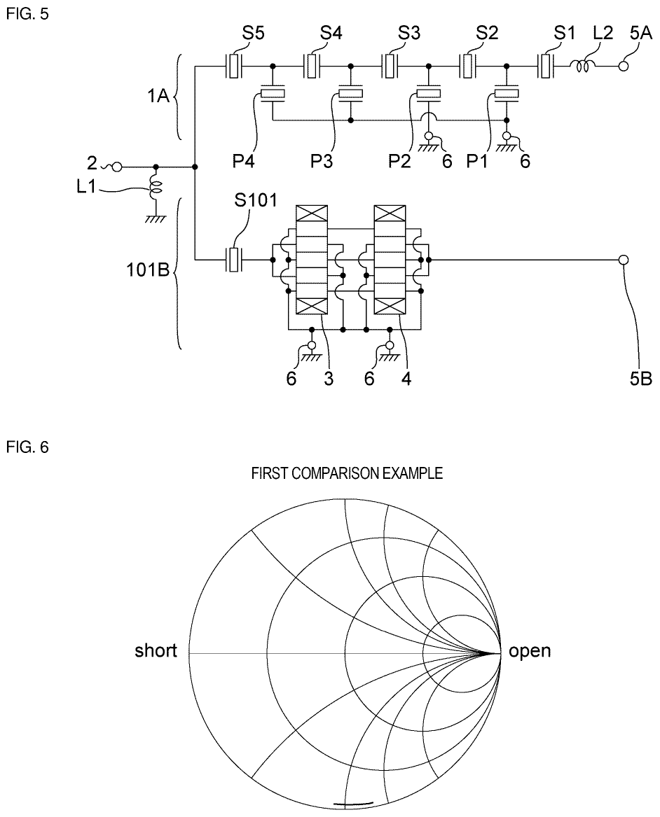

As illustrated in FIG. 5, the first comparison example differs from the first example embodiment in that a receiving filter 101B includes a series-arm resonator S101. The first comparison example also differs from the first example embodiment in that in terms of a circuit configuration of the receiving filter 101B, the series-arm resonator S101 is a resonator that is located closest to the common connection terminal 2. The first comparison example further differs from the first example embodiment in that TC2>C1.

The second comparison example differs from the first example embodiment in that TC2>C1. A circuit configuration of the second comparison examples is the same as the circuit configuration of the first example embodiment.

Design parameters for the first example embodiment, the first comparison example, and the second comparison example are as listed in Table 1 to Table 3. Reference symbols 8A to 8J and symbols 9A to 9F described in Table 1 to Table 3 correspond to reference symbols of the IDT electrodes and the reflectors used herein.

TABLE 1

| | RECEIVING FILTER | | | | | | | | | |
|---|---|---|---|---|---|---|---|---|---|---|
| | FIRST LONGITUDINALLY COUPLED RESONATOR | | | | | | | | | |
| | ACOUSTIC WAVE FILTER 3 | | | | | | | | | |
| | | | | | | | | | | TOTAL OF |
| | | NUMBER OF | | | | | | NUMBER OF | | NUMBER OF |
| | | ELECTRODE FINGERS | | | | | | REFLECTOR | | ELECTRODE |
| | CROSSOVER | OF IDT ELECTRODE | | | | | | ELECTRODE | | FINGERS × |
| | WIDTH OF IDT | [PIECES] | | | | | | FINGERS | | CROSSOVER |
| | ELECTRODE | | | | | | TOTAL | [PIECES] | | WIDTH TC2 |
| | A2 [μm] | 8A | 8B | 8C | 8D | 8E | N2 | 9A | 9B | [PIECES · μm] |
| FIRST EXAMPLE | 66 | 26 | 41 | 45 | 39 | 22 | 173 | 39 | 33 | 11418 |
| EMBODIMENT | | | | | | | | | | |
| FIRST | 88 | 26 | 41 | 45 | 39 | 22 | 173 | 39 | 33 | 15224 |
| COMPARISON | | | | | | | | | | |
| EXAMPLE | | | | | | | | | | |
| SECOND | 88 | 26 | 41 | 45 | 39 | 22 | 173 | 39 | 33 | 15224 |
| COMPARISON | | | | | | | | | | |
| EXAMPLE | | | | | | | | | | |

TABLE 2

| | RECEIVING FILTER | | | | | | | | |
|---|---|---|---|---|---|---|---|---|---|
| | SECOND LONGITUDINALLY COUPLED RESONATOR | | | | | | | | |
| | ACOUSTIC WAVE FILTER 4 | | | | | | | | |
| | | | | | | | | NUMBER OF | |
| | | | | | | | | REFLECTOR | |
| | | NUMBER OF ELECTRODE | | | | | | ELECTRODE | |
| | CROSSOVER | FINGERS OF IDT | | | | | | FINGERS | |
| | WIDTH OF IDT | ELECTRODE [PIECES] | | | | | | [PIECES] | |
| | ELECTRODE [μm] | 8F | 8G | 8H | 8I | 8J | TOTAL | 9C | 9D |
| FIRST EXAMPLE | 118 | 16 | 83 | 31 | 59 | 20 | 209 | 31 | 25 |
| EMBODIMENT | | | | | | | | | |
| FIRST | 118 | 16 | 83 | 31 | 59 | 20 | 209 | 31 | 25 |
| COMPARISON | | | | | | | | | |
| EXAMPLE | | | | | | | | | |
| SECOND | 118 | 16 | 83 | 31 | 59 | 20 | 209 | 31 | 25 |
| COMPARISON | | | | | | | | | |
| EXAMPLE | | | | | | | | | |

TABLE 3

| | TRANSMITTING FILTER | | | | |
|---|---|---|---|---|---|
| | SERIES-ARM RESONATOR S5 | | | | |
| | | | NUMBER OF | | |
| | | NUMBER OF | REFLECTOR | | NUMBER OF |
| | CROSSOVER | ELECTRODE FINGERS | ELECTRODE | | ELECTRODE FINGERS × |
| | WIDTH OF IDT | OF IDT ELECTRODE N1 | FINGERS [PIECES] | | CROSSOVER WIDTH C1 |
| | ELECTRODE A1 [μm] | [PIECES] | 9E | 9F | [PIECES · μm] |
| FIRST EXAMPLE | 76 | 181 | 5 | 5 | 13756 |
| EMBODIMENT | | | | | |
| FIRST | 66 | 181 | 5 | 5 | 11946 |
| COMPARISON | | | | | |
| EXAMPLE | | | | | |
| SECOND | 66 | 181 | 5 | 5 | 11946 |
| COMPARISON | | | | | |
| EXAMPLE | | | | | |

As illustrated in Table 1, in the first example embodiment, the crossover width A2 of all of IDT electrodes is about 66 μm in the first longitudinally coupled resonator acoustic wave filter 3 of the receiving filter 1B. The number of the plurality of electrode fingers of the IDT electrode 8A is 26. Consequently, the product of the number of the plurality of electrode fingers of the IDT electrode 8A and the crossover width A2 is about 1716 [pieces/μm].

Similarly, the product of the numbers of the plurality of electrode fingers of the IDT electrode 8B, the IDT electrode 8C, the IDT electrode 8D, and the IDT electrode 8E and the crossover widths A2 are about 2706 [pieces/μm], 2970 [pieces/μm], about 2574 [pieces/μm], and about 1452 [pieces/μm], respectively. Therefore, the total value TC2 of the product of the plurality of electrode fingers of each of the plurality of IDT electrodes of the first longitudinally coupled resonator acoustic wave filter 3 and the crossover widths A2 is about 11418 [pieces/μm].

With the design parameters listed in Table 1, the crossover widths A2 of all of the IDT electrodes are the same or substantially the same in the first longitudinally coupled resonator acoustic wave filter 3. In this case, the total value of the product of the number of the plurality of electrode fingers of each of the plurality of IDT electrodes of the first longitudinally coupled resonator acoustic wave filter 3 and the crossover widths A2 can be expressed as TC2=N2×A2. That is, in the first example embodiment, the above-described value TC2 is expressed as 173 [pieces]×about 66 [μm]=about 11418 [pieces/μm].

As listed in Table 3, in the first example embodiment, a product C1 of the number of the plurality of electrode fingers N1 of the IDT electrodes 8 of the series-arm resonator S5 of the transmitting filter 1A and a crossover width A1 is 181 [pieces]×about 76 [μm]=about 13756 [pieces/μm]. Therefore, in the first example embodiment, TC2<C1.

On the other hand, as listed in Table 1 and Table 3, in the first comparison example and the second comparison example, TC2=about 15224 [pieces/μm] and C1=about 11946 [pieces/μm]. Therefore, in the first comparison example and the second comparison example, TC2>C1.

Impedance characteristics are compared in the first example embodiment, the first comparison example, and the second comparison example. Specifically, the impedance characteristics are impedance characteristics of the receiving filter in the pass band of the transmitting filter as seen from the common connection terminal. The impedance characteristics are illustrated by a Smith chart. In the Smith chart, the closer the impedance is to the short side, the more likely a signal leaks from the transmitting filter to the receiving filter. On the other hand, the closer the impedance is to the open side, the less likely a signal leaks from the transmitting filter to the receiving filter.

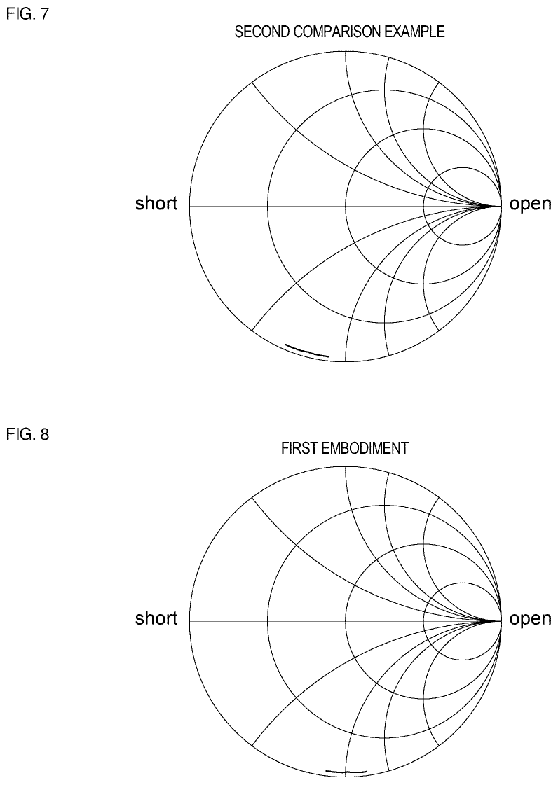

FIG. 6 is a Smith chart illustrating the impedance characteristics of the receiving filter in the pass band of the transmitting filter in the first comparison example, when viewed from the common connection terminal. FIG. 7 is a Smith chart illustrating the impedance characteristics of the receiving filter in the pass band of the transmitting filter in the second comparison example, when viewed from the common connection terminal. FIG. 8 is a Smith chart illustrating the impedance characteristics of the receiving filter in the pass band of the transmitting filter in the first example embodiment, when viewed from the common connection terminal.

As illustrated in FIG. 6, in the first comparison example, the impedance is located closer to the open side compared to the second comparison example illustrated in FIG. 7. As a result, signals are less likely to leak from the transmitting filter 1A as illustrated in FIG. 5 to the receiving filter 101B. In the first comparison example, the series-arm resonator S101 is the resonator that is located closest to the common connection terminal 2 in terms of the circuit configuration of the receiving filter 101B. Consequently, the impedance is located on the open side.

In contrast, as illustrated in FIG. 7, in the second comparison example, the impedance is located closer to the short side compared to the first comparison example illustrated in FIG. 6. As a result, signals are more likely to leak from the transmitting filter to the receiving filter. In the second comparison example, the receiving filter includes no series-arm resonator. Thus, in the second comparison example, the effects such as those of the first comparison example cannot be obtained.

The circuit configuration of the second comparison example is the same or substantially the same as the circuit configuration of the first example embodiment. In spite of this, in the first example embodiment illustrated in FIG. 8, the impedance is located closer to the open side compared to the second example illustrated in FIG. 7. As a result, signals are less likely to leak from the transmitting filter 1A illustrated in FIG. 1 to the receiving filter 1B. Thus, when the duplexer 10 operates, consumed power of the first longitudinally coupled resonator acoustic wave filter 3 of the receiving filter 1B can be reduced. Therefore, the first longitudinally coupled resonator acoustic wave filter 3 is less likely to be damaged.

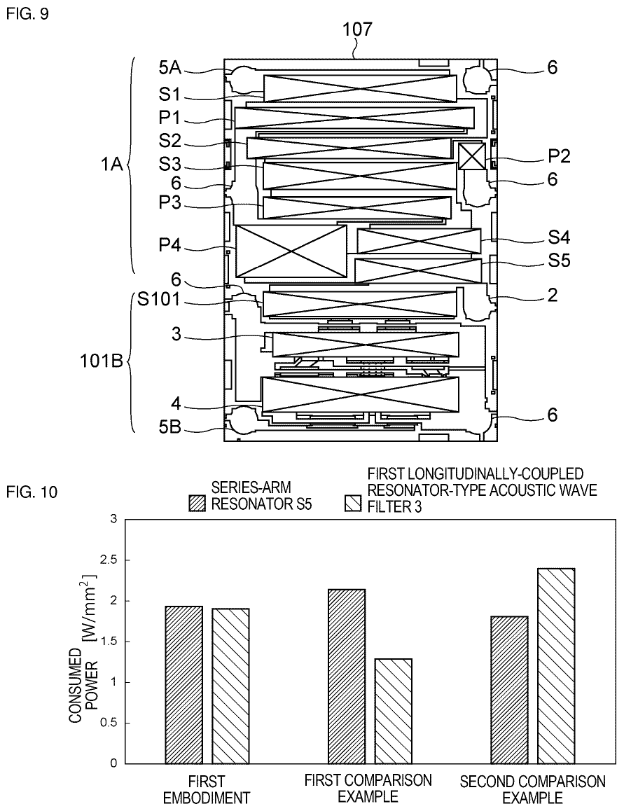

FIG. 9 is a sketch plan view of a duplexer according to the first comparison example.

As evident from a comparison between FIG. 9 and FIG. 2, a piezoelectric substrate 107 in the first comparison example has a larger area than that of the piezoelectric substrate 7 in the first example embodiment. This is because the number of the resonators in the first comparison example is larger than that of the resonators in the first example embodiment. Specifically, no series-arm resonator S101 is provided in the first example embodiment, while the series-arm resonator S101 is provided in the first comparison example.

Conventionally, as in the second comparison example, when the series-arm resonator is not disposed closer to the common connection terminal side than the first longitudinally coupled resonator acoustic wave filter terms of in the circuit configuration of the receiving filter, the impedance is located on the short side, as illustrated in FIG. 7. Thus, in order to bring the impedance closer to the open side, it was necessary to provide the series-arm resonator S101 and to increase the size of the duplexer as in the first comparison example illustrated in FIG. 9.

In contrast, in the first example embodiment illustrated in FIG. 2, damage to the first longitudinally coupled resonator acoustic wave filter 3 can be reduced or prevented without increasing the size of the duplexer 10. Specifically, for example, in the first comparison example, the piezoelectric substrate 107 illustrated in FIG. 9 has the area of about 1 mm×about 1.4 mm. In contrast, for example, in the first example embodiment, the piezoelectric substrate 7 illustrated in FIG. 2 has the area of about 1 mm×about 1.3 mm. Thus, in the first example embodiment, the duplexer 10 can be made smaller by about 7% than that in the first comparison example. In the following, a description will be provided of why the above-described advantageous effects can be obtained.

In acoustic wave resonators, the electrostatic capacitance is proportional to the product of the number of the plurality of electrode fingers of the IDT electrode and the crossover width. On the other hand, the smaller the electrostatic capacitance, the higher the impedance, for example, at frequencies lower than the resonant frequency. That is, in the acoustic wave resonators, the smaller the product of the number of the plurality of electrode fingers of the IDT electrodes and the crossover width, the higher the above-described impedance. Longitudinally coupled resonator acoustic wave filters also have the similar tendency to the acoustic wave resonators. Specifically, in the longitudinally coupled resonator acoustic wave filters, the smaller the total value of the product of the number of the plurality of electrode fingers of each of the plurality of IDT electrodes and the crossover width, the higher the impedance, for example, at frequencies on the outer side of the band used as the pass band.

In the first example embodiment, TC2<C1. That is, the total value TC2 of the products of the number of the plurality of electrode fingers of each of the plurality of IDT electrodes of the first longitudinally coupled resonator acoustic wave filter 3 and the crossover width A2 is smaller than the product C1 of the number of the plurality of electrode fingers N1 of the IDT electrode 8 of the series-arm resonator S5 and the crossover width A1. For this reason, in the first example embodiment, the above-described value TC2 of the first longitudinally coupled resonator acoustic wave filter 3 is relatively small. Thus, in the first longitudinally coupled resonator acoustic wave filter 3, the impedance is relatively high, for example, at frequencies on the outer side of the band used as the pass band of the receiving filter 1B. More specifically, in the first longitudinally coupled resonator acoustic wave filter 3 of the receiving filter 1B, the impedance is relatively high in the pass band of the transmitting filter 1A.

As a result, the impedance of the receiving filter 1B in the pass band of the transmitting filter 1A is located on the open side, when viewed from the common connection terminal 2 of the duplexer 10. This makes it possible to reduce the consumed power of the first longitudinally coupled resonator acoustic wave filter 3 of the receiving filter 1B, when the duplexer 10 operates.

In this manner, the consumed power of the first longitudinally coupled resonator acoustic wave filter 3 can be reduced without providing the series-arm resonator closer to the common connection terminal 2 side than the first longitudinally coupled resonator acoustic wave filter 3. Therefore, it is possible to make the first longitudinally coupled resonator acoustic wave filter 3 less likely to be damaged without increasing the size of the duplexer 10.

It will be specifically described below that the consumed power of the first longitudinally coupled resonator acoustic wave filter 3 can be reduced in the first example embodiment.

In the first example embodiment, the first comparison example, and the second comparison example, a comparison was made of the consumed power of the first longitudinally coupled resonator acoustic wave filters of the receiving filter. In addition to this, in the first example embodiment, the first comparison example, and the second comparison example, a comparison was made of the consumed power of the series-arm resonator that is located closest to the common connection terminal in terms of the circuit configuration of the transmitting filter.

As illustrated in FIG. 1 or FIG. 5, the series-arm resonator located closest to the common connection terminal in terms of the circuit configuration of the transmitting filter is the series-arm resonator S5. For this reason, in the following, the series-arm resonator may be simply referred to as the series-arm resonator S5.

In the comparison, the consumed power of the first longitudinally coupled resonator acoustic wave filter 3 and the series-arm resonator S5 was calculated by simulation. Specifically, the simulation is a simulation in which electric power is applied to the first signal terminal 5A of the transmitting filter 1A at the highest frequency in the pass band of the transmitting filter 1A.

FIG. 10 is a diagram illustrating the consumed power of the series-arm resonator located closest to the common connection terminal in terms of the circuit configuration of the transmitting filter and the consumed power of the first longitudinally coupled resonator acoustic wave filter of the receiving filter, in the first example embodiment, the first comparison example, and the second comparison example.

As described above, in the first example embodiment and the second comparison example, the first longitudinally coupled resonator acoustic wave filter 3 is the resonator that is located closest to the common connection terminal 2 in terms of the circuit configuration of the receiving filter. In a comparison between duplexers having such a circuit configuration, the consumed power of the first longitudinally coupled resonator acoustic wave filter 3 is smaller in the first example embodiment than in the second comparison example. Therefore, the first longitudinally coupled resonator acoustic wave filter 3 is less likely to be damaged in the first example embodiment.

Among the first example embodiment, the first comparison example, and the second comparison example, the first longitudinally coupled resonator acoustic wave filter 3 in the first comparison example has the smallest consumed power. This is because, in the first comparison example, the series-arm resonator S101 is located closer to the common connection terminal 2 side than in the first longitudinally coupled resonator acoustic wave filter 3, in terms of the circuit configuration of the receiving filter 101B illustrated in FIG. 5.

More particularly, in the first comparison example, even when a signal leaks from the transmitting filter 1A to the receiving filter 101B, the largest electric power is applied to the series-arm resonator S101 located closest to the common connection terminal 2, in terms of the circuit configuration of the receiving filter 101B. Thus, in the first comparison example, the consumed power of the first longitudinally coupled resonator acoustic wave filter 3 becomes smaller due to the circuit configuration. Nevertheless, as described above, the size of the duplexer is increased in the first comparison example.

As illustrated in FIG. 10, in the first example embodiment, the consumed power of the series-arm resonator S5 is smaller than that in the first comparison example. This is because, in the first example embodiment, the product C1 of the number N1 of the plurality of electrode fingers of the series-arm resonator S5 and the crossover width A1 is larger than that in the first comparison example.

More particularly, in the series-arm resonator S5, the larger the above-described product C1, the larger the electrostatic capacitance. In the series-arm resonator S5, the larger the electrostatic capacitance, the lower the impedance, for example, at frequencies lower than the resonant frequency. That is, in the first example embodiment, the impedance of the series-arm resonator S5 is smaller than in the first comparison example, and thus, the consumed power of the series-arm resonator S5 is small. Therefore, the series-arm resonator S5 is less likely to be damaged in the first example embodiment.

In the first example embodiment, both of the transmitting filter 1A and the receiving filter 1B are more likely to be damaged. Thus, in the first example embodiment, the electric power handling capability of the duplexer 10 can be increased compared to the first comparison example and the second comparison example.

In addition, in the first example embodiment, with the impedance of the series-arm resonator S5 being smaller, impedance matching on the common connection terminal 2 side can be improved.

More particularly, in the first comparison example illustrated in FIG. 5, the resonator located closest to the common connection terminal 2 is the series-arm resonator S101 in terms of the circuit configuration of the receiving filter 101B. In this case, the impedance matching on the common connection terminal 2 side is improved by increasing the impedance of the series-arm resonator S5, which is the resonator located closest to the common connection terminal 2, in terms of the circuit configuration of the transmitting filter 1A. In contrast, no series-arm resonator S101 is provided in the first example embodiment. In this case, the impedance matching on the common connection terminal 2 side is improved by reducing the impedance of the series-arm resonator S5.

Therefore, in the first example embodiment, it is possible to obtain both the advantageous effect of increasing the electric power handling capability of the duplexer 10 and the advantageous effect of improving the impedance matching on the common connection terminal 2 side.

Furthermore, attenuation frequency characteristics of the transmitting filter and the receiving filter were compared in the first example embodiment, the first comparison example, and the second comparison example.

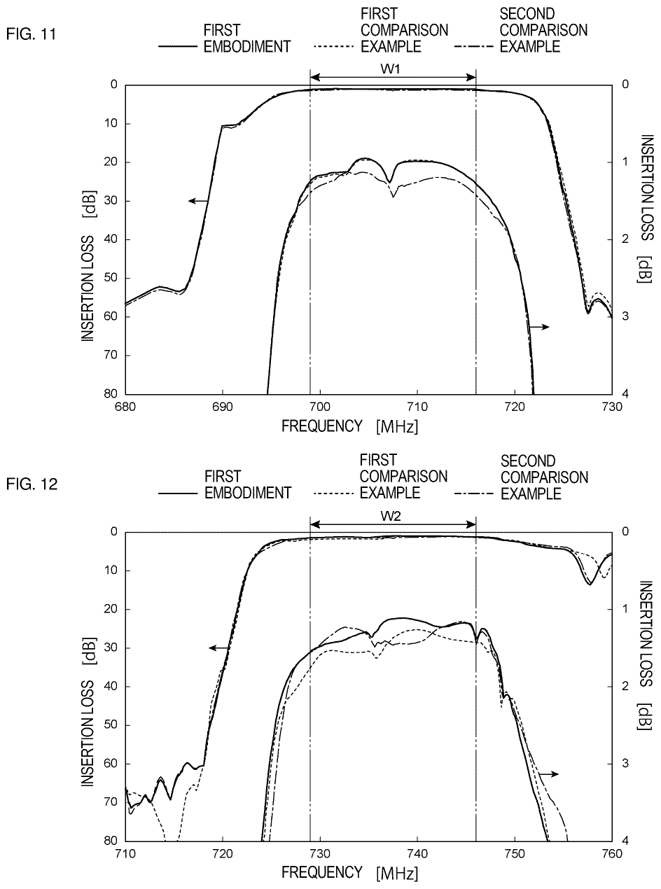

FIG. 11 is a diagram illustrating the attenuation frequency characteristics of the transmitting filters in the first example embodiment, the first comparison example, and the second comparison example. FIG. 12 is a diagram illustrating the attenuation frequency characteristics of the transmitting filters in the first example embodiment, the first comparison example, and the second comparison example. The double-headed arrow W1 in FIG. 11 indicates the pass band of the transmitting filter. The double-headed arrow W2 in FIG. 12 indicates the pass band of the receiving filter.

As illustrated in FIG. 11, the insertion filter of the transmitting filter in the first example embodiment is smaller than the insertion loss of the transmitting filter in the second comparison example. Specifically, in the first example embodiment, the maximum absolute value of the insertion loss in the pass band of the transmitting filter is about 1.28 dB. In the second comparison example, the maximum absolute value of the insertion loss in the pass band of the transmitting filter is about 1.43 dB. The insertion losses of the transmitting filters in the first example embodiment and the first comparison example are the same or substantially the same.

As illustrated in FIG. 12, the insertion loss of the receiving filter in the first example embodiment is smaller than the insertion loss of the receiving filter in the first comparison example. Specifically, in the first example embodiment, the maximum absolute value of the insertion loss in the pass band of the receiving filter is about 1.55 dB. In the first comparison example, the maximum absolute value of the insertion loss in the pass band of the receiving filter is about 1.75 dB. In the second comparison example, the maximum absolute value of the insertion loss in the pass band of the receiving filter is about 1.56 dB. Thus, the insertion losses of the receiving filters in the first example embodiment and the second comparison example are the same or substantially the same.

As described above, in the first example embodiment, the insertion losses in both of the transmitting filter and the receiving filter can be reduced. This is because of the following reasons.

In the first example embodiment illustrated in FIG. 1, it is possible to reduce or prevent leakage of signals from the transmitting filter 1A to the receiving filter 1B as described above. This makes it possible to reduce the insertion loss of the transmitting filter 1A.

Furthermore, in the first example embodiment, the series-arm resonator S101 illustrated in FIG. 5 is not provided. This makes it possible to avoid an increase in the insertion loss caused by providing the series-arm resonator S101. In addition, in the first example embodiment, the crossover width A2 of each of the IDT electrodes in the first longitudinally coupled resonator acoustic wave filter 3 is narrower than that in the first comparison example. For this reason, in the first example embodiment, electric resistance in each of the above-described IDT electrodes is lower. Thus, in the receiving filter 1B, the insertion loss due to the first longitudinally coupled resonator acoustic wave filter 3 is small. Therefore, it is possible to reduce the insertion loss of the receiving filter 1B in the first example embodiment.

In the meantime, in the first example embodiment, a relationship TC2<C1 is satisfied. That is, the total value TC2 of the product of the number of the plurality of electrode fingers of each of the plurality of IDT electrodes of the first longitudinally coupled resonator acoustic wave filter 3 and the crossover width A2 is smaller than the product C1 of the number N1 of the plurality of electrode fingers of the IDT electrodes 8 of the series-arm resonator S5 and the crossover width A1. This relationship can also be expressed as a relationship of the electrostatic capacitances in the first longitudinally coupled resonator acoustic wave filter 3 and the series-arm resonator S5.

Specifically, in the acoustic wave resonator such as the series-arm resonator S5, the electrostatic capacitance is proportional to the product of the number of the plurality of electrode fingers of the IDT electrode and the crossover width. In the longitudinally coupled resonator acoustic wave filter, the electrostatic capacitance is proportional to the total value of the product of the number of the plurality of electrode fingers of each of the plurality of IDT electrodes and the crossover width. Thus, in the first example embodiment, the electrostatic capacitance of the first longitudinally coupled resonator acoustic wave filter 3 is smaller than the electrostatic capacitance in the series-arm resonator S5. This makes it possible to reduce or prevent the damage to the first longitudinally coupled resonator acoustic wave filter 3 without increasing the size of the duplexer 10.

More particularly, the electrostatic capacitance of a resonator is proportional to a duty ratio. That is, the electrostatic capacitance of the resonator is proportional to a value obtained by further multiplying the product of the number of the plurality of electrode fingers of the IDT electrodes and the crossover width by the duty ratio. Here, the duty ratio is a proportion of a portion of the piezoelectric substrate covered by the electrode fingers in the electrode finger orthogonal direction. For example, the duty ratio in a certain region is a value obtained by dividing total dimensions, along the electrode finger orthogonal direction, of the portion of the piezoelectric substrate covered by the electrode fingers, by dimensions of the region along the electrode finger orthogonal direction.

Nevertheless, in many cases, in acoustic wave filters, the duty ratio is generally the same or substantially the same in any region within one IDT electrode. Similarly, in many cases, the duty ratio is generally the same or substantially the same in any region among the plurality of IDT electrodes. In this case, there is no need to consider the duty ratio when comparing the electrostatic capacitances between resonators. Then, in the first example embodiment, the duty ratio is the same or substantially the same in any region of any IDT electrode between the series-arm resonator S5 and the first longitudinally coupled resonator acoustic wave filter 3. As described above, because the relationship TC2<C1 is satisfied, the electrostatic capacitance of the first longitudinally coupled resonator acoustic wave filter 3 is smaller than the electrostatic capacitance of the series-arm resonator S5.

On the other hand, there are cases in which the duty ratio may differ in each region within one IDT electrode or among a plurality of IDT electrodes. For example, when the duty ratios in a plurality of regions differ from each other within one IDT electrode in an acoustic wave resonator, it can be said that the electrostatic capacitance of the acoustic wave resonator is a combined electrostatic capacitance obtained by combining the electrostatic capacitances in all regions. In this case, it may be considered that each of the plurality of regions is an acoustic wave resonator and that a plurality of the acoustic wave resonators is connected in parallel with each other. That is, a sum of the electrostatic capacitances in all of the regions is the electrostatic capacitance of the above-described acoustic wave resonator. Even when the duty ratios in a plurality of regions of a plurality of IDT electrodes in a longitudinally coupled resonator acoustic wave filter differ from each other, the sum of the electrostatic capacitances in all of the regions is the electrostatic capacitance of the longitudinally coupled resonator acoustic wave filter.

In the following, a value obtained by further multiplying the product of the number of the plurality of electrode fingers and the crossover width by the duty ratio may be referred to as a comparison reference value. If the comparison reference value is used when comparing the electrostatic capacitances between resonators, the comparison reference value may be treated in the same manner as the electrostatic capacitance. Specifically, when the duty ratios in a plurality of regions differ from each other within one IDT electrode in an acoustic wave resonator, a sum of the comparison reference values in all of the regions may be treated as a value that corresponds to the comparison reference value in the acoustic wave resonator. When the duty ratios in a plurality of regions of a plurality of IDT electrodes in a longitudinally coupled resonator acoustic wave filter differ from each other, a sum of the comparison reference values in all of the regions may be treated as a value that corresponds to the comparison reference value of the longitudinally coupled resonator acoustic wave filter.

For example, given that n is a natural number, it is assumed that the series-arm resonator S5, which is an acoustic wave resonator, includes n regions. In this case, it is assumed that a is a natural number which is 1 or more and n or less, the number of the electrode fingers in an a^{th} region in the IDT electrode of the series-arm resonator S5 is I1a, and the duty ratio is da. In this example, it is assumed that the crossover width of the series-arm resonator S5 is A1 in all regions. When the comparison reference value in the series-arm resonator S5 is B1, B1 can be expressed as B1=Σ[(I1a×A1)×da](1≤a≤n).

The number of the regions in the series-arm resonator S5 may be the number obtained by adding 1 to a total number of boundaries between regions where the duty ratios differ from each other. When the duty ratio in the IDT electrodes of the series-arm resonator S5 is constant as in the first example embodiment, the number of regions is one.

On the other hand, it is assumed that m is a natural number and the first longitudinally coupled resonator acoustic wave filter 3 includes m regions. In this case, it is assumed that b is a natural number which is 1 or more and m or less, the number of the electrode fingers in a b^{th} region in the plurality of IDT electrodes of the first longitudinally coupled resonator acoustic wave filter 3 is I2b, and the duty ratio is db. In this example, it is assumed that the crossover width of the first longitudinally coupled resonator acoustic wave filter is A2 in all of the regions. Given that the comparison reference value in the first longitudinally coupled resonator acoustic wave filter 3 is B2, B2 can be expressed as B2=Σ[(I2b×A2)×db](1≤b≤m).

The number of the regions in the first longitudinally coupled resonator acoustic wave filter 3 may be the number obtained by adding 1 to the total number of the boundaries where the duty ratios differ from each other. When the duty ratio in the plurality of IDT electrodes of the first longitudinally coupled resonator acoustic wave filter 3 is constant as in the first example embodiment, the number of regions is one.

When B2<B1, the electrostatic capacitance of the first longitudinally coupled resonator acoustic wave filter 3 is smaller than the electrostatic capacitance of the series-arm resonator S5.

In the following, a preferred configuration of the first example embodiment will be described. It is also possible to use the configuration in multiplexers according to example embodiments of the present invention other than the first example embodiment.

First, as illustrated in FIG. 1, the series-arm resonator S5 is the resonator that is located closest to the common connection terminal 2 in terms of the circuit configuration of the transmitting filter 1A. The first longitudinally coupled resonator acoustic wave filter 3 is the resonator that is located closest to the common connection terminal 2 in terms of the circuit configuration of the receiving filter 1B. Then, as illustrated in FIG. 4, the number of the plurality of electrode fingers of the IDT electrodes 8 of the series-arm resonator S5 is N1. As illustrated in FIG. 3, the total number of the plurality of electrode fingers of the plurality of IDT electrodes of the first longitudinally coupled resonator acoustic wave filter 3 is N2. When a comparison is made between the above-described number N1 and the above-described total number N2, it is preferable that N2<N1. This makes it possible to increase the electric power handling capability of the transmitting filter 1A and reduce the insertion loss of the receiving filter 1B.

More particularly, because the number N1 of the plurality of electrode fingers of the IDT electrodes 8 of the series-arm resonator S5 is large, the electric resistance of the IDT electrodes 8 can be reduced. This can reduce the consumed power of the series-arm resonator S5. Thus, it is possible to increase the electric power handling capability of the series-arm resonator S5 and increase the electric power handling capability of the transmitting filter 1A.

On the one hand, the total number N2 of the plurality of electrode fingers of the plurality of IDT electrodes of the first longitudinally coupled resonator acoustic wave filter 3 is small. Here, the electrostatic capacitance of the first longitudinally coupled resonator acoustic wave filter 3 is proportional to the product TC2 of the above-described total number N2 and the crossover width A2. Therefore, in order to have desired electrostatic capacitance in the first longitudinally coupled resonator acoustic wave filter 3, the product TC2 of the above-described total number N2 and the crossover width A2 is adjusted to a desired value. At this time, if the above-described total number N2 is small, the crossover width A2 can be widened. This can reduce or prevent the leakage of the acoustic wave in the electrode finger extension direction in the first longitudinally coupled resonator acoustic wave filter 3. Therefore, it is possible to reduce the insertion loss of the receiving filter 1B.

When a wavelength defined by an electrode finger pitch is A, it is preferable that the crossover width A2 in the plurality of IDT electrodes of the first longitudinally coupled resonator acoustic wave filter 3 is about 10λ or more, for example. This makes it possible to more reliably reduce or prevent the leakage of the acoustic wave in the electrode finger extension direction. The electrode finger pitch is a center-to-center distance between adjacent electrode fingers in the electrode finger orthogonal direction. In the first example embodiment according to the comparison illustrated in FIG. 10 and the like, the crossover width A2 is, for example, about 12.8λ.

On the other hand, when the crossover width A2 in each of the IDT electrodes of the first longitudinally coupled resonator acoustic wave filter 3 is too wide, the electric resistance of each IDT electrode is higher. Nevertheless, in the first example embodiment, because TC2<C1, the product TC2 of the total number N2 of the plurality of electrode fingers of the plurality of IDT electrodes of the first longitudinally coupled resonator acoustic wave filter 3 and the crossover width A2 is small. Thus, the crossover width A2 can be set to a suitable value.

As illustrated in FIG. 3, in the receiving filter 1B, the IDT electrodes connected to the input potential of the first longitudinally coupled resonator acoustic wave filter 3 include the IDT electrode 8B and the IDT electrode 8D. The IDT electrodes connected to the output potential include the IDT electrode 8A, the IDT electrode 8C, and the IDT electrode 8E. In this manner, in the first longitudinally coupled resonator acoustic wave filter 3, it is preferable that the number of the IDT electrodes connected to the input potential is smaller than the number of the IDT electrodes connected to the output potential. This makes it possible to reduce the insertion loss of the transmitting filter 1A.

More particularly, in the first example embodiment, when viewed from the common connection terminal 2 of the duplexer 10, the impedance of the receiving filter 1B in the pass band of the transmitting filter 1A is located on the open side, as illustrated in FIG. 8. This makes it difficult for signals to leak from the transmitting filter 1A to the receiving filter 1B. Here, in terms of the circuit configuration of the receiving filter 1B, the resonator located closest to the common connection terminal 2 is the first longitudinally coupled resonator acoustic wave filter 3. Therefore, in order to position the above-described impedance of the receiving filter 1B on the open side, it is only necessary to increase the impedance of the first longitudinally coupled resonator acoustic wave filter 3 on the common connection terminal 2 side.

The impedance of the first longitudinally coupled resonator acoustic wave filter 3 on the common connection terminal 2 side is larger as the number of the IDT electrodes connected to the common connection terminal 2 side is smaller. In the first longitudinally coupled resonator acoustic wave filter 3 included in the receiving filter 1B, the portion connected to the common connection terminal 2 side is the portion connected to the input potential, and the portion connected to the second signal terminal 5B side is the portion connected to the output potential. Therefore, the impedance on the common connection terminal 2 side in the first longitudinally coupled resonator acoustic wave filter 3 is higher as the number of the IDT electrodes of the first longitudinally coupled resonator acoustic wave filter 3 connected to the input potential is smaller.

In the first example embodiment, in the first longitudinally coupled resonator acoustic wave filter 3, the number of the IDT electrodes connected to the input potential is smaller than the number of the IDT electrodes connected to the output potential. This makes it possible to increase the impedance of the first longitudinally coupled resonator acoustic wave filter 3 on the common connection terminal 2 side. As a result, in the impedance characteristics illustrated in FIG. 8, the impedance can be positioned on the open side, which can make it difficult for signals to leak from the transmitting filter 1A to the receiving filter 1B. Therefore, it is possible to reduce the insertion loss of the transmitting filter 1A.

As illustrated in FIG. 2, a common connection wiring 12 connected to the common connection terminal 2 is provided on the piezoelectric substrate 7. The series-arm resonator S5 of the transmitting filter 1A and the first longitudinally coupled resonator acoustic wave filter 3 of the receiving filter 1B are connected in common to the common connection wiring 12. The common connection wiring 12 might not necessarily be provided. The series-arm resonator S5 and the first longitudinally coupled resonator acoustic wave filter 3 may be connected to the common connection terminal 2 by separate wiring.

Nevertheless, as illustrated in FIG. 2, in the electrode finger extension direction of the series-arm resonator S5, the series-arm resonator S5 and the first longitudinally coupled resonator acoustic wave filter 3 preferably face each other with the common connection wiring 12 interposed therebetween. This makes it possible to reduce the insertion loss of the transmitting filter 1A.

More particularly, in the above-described configuration, the portion of the series-arm resonator S5 of the transmitting filter 1A on the common connection terminal 2 side and the portion of the first longitudinally coupled resonator acoustic wave filter 3 of the receiving filter 1B on the common connection terminal 2 side are electrically connected in common by the common connection wiring 12. Then, the common connection wiring 12 is connected to the common connection terminal 2. The common connection terminal 2 is a terminal to which the series-arm resonator S5 and the first longitudinally coupled resonator acoustic wave filter 3 are connected in common. Therefore, it can be said that electrically, the common connection wiring 12 is a portion of the common connection terminal 2. Thus, the above-described configuration corresponds to a configuration in which a length of the wiring which connects the first longitudinally coupled resonator acoustic wave filter 3 and the common connection terminal 2 is very short.

The shorter the length of the wiring, the smaller inductance component in the wiring. Therefore, the inductance component is small between the first longitudinally coupled resonator acoustic wave filter 3 and the common connection terminal 2.

Here, in the Smith chart as in FIG. 8, when the inductance component is large, the impedance is located at a position far along the counterclockwise direction on a constant resistance circle. The constant resistance circle refers to each circle in the Smith chart of FIG. 8. When the inductance component is large, the impedance is located on the short side in the impedance characteristics illustrated in FIG. 8.

In contrast, in the above-described configuration illustrated in FIG. 2, the inductance component is small between the first longitudinally coupled resonator acoustic wave filter 3 and the common connection terminal 2. Thus, in the above-described configuration, the impedance can be positioned on the open side in the impedance characteristics of the receiving filter 1B in the pass band of the transmitting filter 1A, when viewed from the common connection terminal 2. This makes it difficult for signals to leak from the transmitting filter 1A to the receiving filter 1B. Therefore, it is possible to reduce the insertion loss of the transmitting filter 1A.

It is preferable that the receiving filter 1B includes the second longitudinally coupled resonator acoustic wave filter 4, and that the crossover width A2 in the first longitudinally coupled resonator acoustic wave filter 3 is narrower than the crossover width in the second longitudinally coupled resonator acoustic wave filter 4. This makes it possible to reduce the insertion loss of the receiving filter 1B.

More particularly, as described above, because TC2<C1 in the first example embodiment, the electrostatic capacitance of the first longitudinally coupled resonator acoustic wave filter 3 is small. In this case, the impedance is located higher than about 5022 in the impedance characteristics in the pass band of the receiving filter 1B illustrated in the Smith chart. In other words, the impedance is located to the right of the center in the Smith chart.

Nevertheless, in the first example embodiment, the receiving filter 1B includes the second longitudinally coupled resonator acoustic wave filter 4. In addition, the crossover width A2 in the first longitudinally coupled resonator acoustic wave filter 3 is narrower than the crossover width in the second longitudinally coupled resonator acoustic wave filter 4. This makes it possible to correct an offset of the impedance in the pass band of the receiving filter 1B from the center of the Smith chart. Specifically, the impedance can be positioned around 50Ω in the Smith chart. This makes it possible to reduce the insertion loss of the receiving filter 1B.

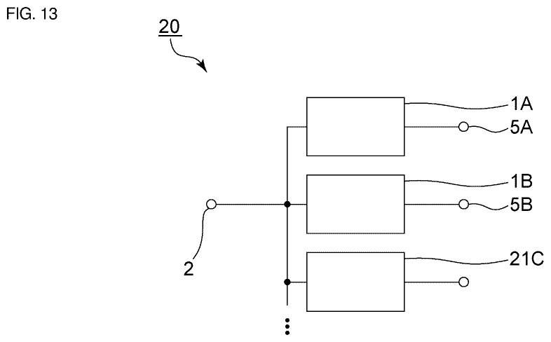

FIG. 13 is a schematic diagram of a multiplexer according to a second example embodiment of the present invention.

A multiplexer 20 of the present example embodiment includes the common connection terminal 2 and three or more filter devices. Specifically, the multiplexer 20 includes the transmitting filter 1A, the receiving filter 1B, a filter device 21C, and at least one other filter device. The transmitting filter 1A, the receiving filter 1B, the filter device 21C, and the other filter device are connected in common to the common connection terminal 2.

The transmitting filter 1A and the receiving filter 1B are the receiving filter and the transmitting filter that are the same as or similar to the first example embodiment. The filter device 21C may be, for example, a receiving filter or a transmitting filter. This also applies to filter devices other than the transmitting filter 1A, the receiving filter 1B, and the filter device 21C.

In the multiplexer 20 of the present example embodiment as well, similarly to the first example embodiment, it is also possible to reduce or prevent damage to the first longitudinally coupled resonator acoustic wave filter 3 of the receiving filter 1B without increasing the size. In addition, it is also possible to reduce the insertion losses of the transmitting filter 1A and the receiving filter 1B.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multiplexer comprising:
a common connection terminal; and
a transmitting filter and a receiving filter connected in common to the common connection terminal; wherein
the transmitting filter and the receiving filter each include a resonator;
the resonator of the transmitting filter and the resonator of the receiving filter share a piezoelectric substrate;
the resonator located closest to the common connection terminal in terms of a circuit configuration of the transmitting filter defines a series-arm resonator;
the resonator located closest to the common connection terminal in terms of a circuit configuration of the receiving filter defines a longitudinally coupled resonator acoustic wave filter;
the series-arm resonator of the transmitting filter includes an IDT electrode including a plurality of electrode fingers;
the longitudinally coupled resonator acoustic wave filter of the receiving filter includes a plurality of IDT electrodes each including a plurality of electrode fingers;
in each of the IDT electrodes of the longitudinally coupled resonator acoustic wave filter and the series-arm resonator, when a direction in which the plurality of electrode fingers extends is denoted as an electrode finger extension direction and a direction orthogonal or substantially orthogonal to the electrode finger extension direction is denoted as an electrode finger orthogonal direction, a region where the plurality of electrode fingers adjacent to each other in the electrode finger orthogonal direction overlap is a crossover region, and a dimension of the crossover region along the electrode finger extension direction is a crossover width; and
when in the transmitting filter, a product of a number of the plurality of electrode fingers of the IDT electrode of the series-arm resonator and the crossover width is denoted as C1, and in the receiving filter, when a total value of a product of the number of the plurality of electrode fingers of each of the plurality of IDT electrodes of the longitudinally coupled resonator acoustic wave filter and the crossover width is denoted as TC2, TC2<C1.

2. The multiplexer according to claim 1, wherein, when in the transmitting filter, the number of the plurality of electrode fingers of the IDT electrode of the series-arm resonator is denoted as N1, and in the receiving filter, a total number of the plurality of electrode fingers of the plurality of IDT electrodes of the longitudinally coupled resonator acoustic wave filter is denoted as N2, N2<N1.

3. The multiplexer according to claim 1, wherein, in the longitudinally coupled resonator acoustic wave filter of the receiving filter, the plurality of IDT electrodes includes IDT electrodes connected to an input potential and IDT electrodes connected to an output potential, and a number of the IDT electrodes connected to the input potential is smaller than a number of the IDT electrodes connected to the output potential.

4. The multiplexer according to claim 1, further comprising:
a common connection wiring on the piezoelectric substrate and to which the series-arm resonator of the transmitting filter and the longitudinally coupled resonator acoustic wave filter of the receiving filter are connected in common; wherein
when in the IDT electrode of the series-arm resonator, a direction in which the plurality of electrode fingers extends is denoted as an electrode finger extension direction, the series-arm resonator and the longitudinally coupled resonator acoustic wave filter face each other with the common connection wiring interposed therebetween, in the electrode finger extension direction of the series-arm resonator; and
the common connection wiring is connected to the common connection terminal.

5. The multiplexer according to claim 1, wherein
the longitudinally coupled resonator acoustic wave filter of the receiving filter defines a first longitudinally coupled resonator acoustic wave filter, the receiving filter further includes at least one second longitudinally coupled resonator acoustic wave filter other than the first longitudinally coupled resonator acoustic wave filter, and the at least one second longitudinally coupled resonator acoustic wave filter includes a plurality of IDT electrodes each including a plurality of electrode fingers;
in each of the IDT electrodes of the first longitudinally coupled resonator acoustic wave filter and the second longitudinally coupled resonator acoustic wave filter, when a direction in which the plurality of electrode fingers extends is denoted as an electrode finger extension direction and a direction that is orthogonal or substantially orthogonal to the electrode finger extension direction is defined as an electrode finger orthogonal direction, a region where the electrode fingers adjacent to each other in the electrode finger orthogonal direction overlap is a crossover region, and a dimension of the crossover region along the electrode finger extension direction is denoted as a crossover width; and
the crossover width in the first longitudinally coupled resonator acoustic wave filter is narrower than the crossover width in the second longitudinally coupled resonator acoustic wave filter.

6. The multiplexer according to claim 1, further comprising at least one filter device connected to the common connection terminal in common with the transmitting filter and the receiving filter.

7. The multiplexer according to claim 1, wherein the common connection terminal defines an antenna terminal.

8. The multiplexer according to claim 1, wherein
a pass band of the transmitting filter is about 699 MHz to about 716 MHz; and
a pass band of the receiving filter is about 729 MHz to about 746 MHz.

9. The multiplexer according to claim 1, wherein the piezoelectric substrate includes lithium tantalate, lithium niobate, zinc oxide, aluminum oxide, crystal, or lead zirconate titanate.

10. A multiplexer comprising:
a common connection terminal; and
a transmitting filter and a receiving filter connected in common to the common connection terminal; wherein
the transmitting filter and the receiving filter each include a resonator;
the resonator of the transmitting filter and the resonator of the receiving filter share a piezoelectric substrate;
the resonator located closest to the common connection terminal in terms of a circuit configuration of the transmitting filter defines a series-arm resonator;
the resonator located closest to the common connection terminal in terms of a circuit configuration of the receiving filter defines a longitudinally coupled resonator acoustic wave filter;
the series-arm resonator of the transmitting filter includes an IDT electrode including a plurality of electrode fingers;
the longitudinally coupled resonator acoustic wave filter of the receiving filter includes a plurality of IDT electrodes each including a plurality of electrode fingers; and
electrostatic capacitance of the longitudinally coupled resonator acoustic wave filter of the receiving filter is smaller than electrostatic capacitance of the series-arm resonator of the transmitting filter.

11. The multiplexer according to claim 10, wherein, when in the transmitting filter, a number of the plurality of electrode fingers of the IDT electrode of the series-arm resonator is denoted as N1, and in the receiving filter, a total number of the plurality of electrode fingers of the plurality of IDT electrodes of the longitudinally coupled resonator acoustic wave filter is denoted as N2, N2<N1.

12. The multiplexer according to claim 10, wherein, in the longitudinally coupled resonator acoustic wave filter of the receiving filter, the plurality of IDT electrodes includes IDT electrodes connected to an input potential and IDT electrodes connected to an output potential, and a number of the IDT electrodes connected to the input potential is smaller than a number of the IDT electrodes connected to the output potential.

13. The multiplexer according to claim 10, further comprising:
a common connection wiring on the piezoelectric substrate and to which the series-arm resonator of the transmitting filter and the longitudinally coupled resonator acoustic wave filter of the receiving filter are connected in common; wherein
when in the IDT electrode of the series-arm resonator, a direction in which the plurality of electrode fingers extends is denoted as an electrode finger extension direction, the series-arm resonator and the longitudinally coupled resonator acoustic wave filter face each other with the common connection wiring interposed therebetween, in the electrode finger extension direction of the series-arm resonator; and
the common connection wiring is connected to the common connection terminal.

14. The multiplexer according to claim 10, wherein
the longitudinally coupled resonator acoustic wave filter of the receiving filter defines a first longitudinally coupled resonator acoustic wave filter, the receiving filter further includes at least one second longitudinally coupled resonator acoustic wave filter other than the first longitudinally coupled resonator acoustic wave filter, and the at least one second longitudinally coupled resonator acoustic wave filter includes a plurality of IDT electrodes each including a plurality of electrode fingers;
in each of the IDT electrodes of the first longitudinally coupled resonator acoustic wave filter and the second longitudinally coupled resonator acoustic wave filter, when a direction in which the plurality of electrode fingers extends is denoted as an electrode finger extension direction and a direction that is orthogonal or substantially orthogonal to the electrode finger extension direction is defined as an electrode finger orthogonal direction, a region where the electrode fingers adjacent to each other in the electrode finger orthogonal direction overlap is a crossover region, and a dimension of the crossover region along the electrode finger extension direction is denoted as a crossover width; and
the crossover width in the first longitudinally coupled resonator acoustic wave filter is narrower than the crossover width in the second longitudinally coupled resonator acoustic wave filter.

15. The multiplexer according to claim 10, further comprising at least one filter device connected to the common connection terminal in common with the transmitting filter and the receiving filter.

16. The multiplexer according to claim 10, wherein the common connection terminal defines an antenna terminal.

17. The multiplexer according to claim 10, wherein
a pass band of the transmitting filter is about 699 MHz to about 716 MHz; and
a pass band of the receiving filter is about 729 MHz to about 746 MHz.

18. The multiplexer according to claim 10, wherein the piezoelectric substrate includes lithium tantalate, lithium niobate, zinc oxide, aluminum oxide, crystal, or lead zirconate titanate.
